(19) United States
(12) Patent Application Publication
(10) Pub. No.: US 2025/0054424 A1
(43) Pub. Date: Feb. 13, 2025

(54) DISPLAY PIXEL WITH LIGHT-EMITTING DIODES FOR DISPLAY SCREEN

(71) Applicant: Aledia, Echirolles (FR)

(72) Inventors: Frédéric Mercier, Coublevie (FR); Ivan Petkov, Saint Martin D'Heres (FR)

(73) Assignee: Aledia, Echirolles (FR)

(21) Appl. No.: 18/721,643

(22) PCT Filed: Dec. 12, 2022
(86) PCT No.: PCT/EP2022/085276

§ 371 Date: Jun. 18, 2024

(30) Foreign Application Priority Data
Dec. 22, 2021 (FR) 2114278

(51) Int. Cl. G09G 3/00; G09G 3/32

(52) U.S. Cl. CPC G09G 3/006; G09G 3/32

(57) ABSTRACT

A display pixel comprising at least one light-emitting diode, an electronic circuit for driving the light-emitting diode, and first and second conductive pads, the first pad being coupled to the light-emitting diode, the driving circuit being configured in normal operation to drive the light-emitting diode on the basis of first signals received on the second pad, the driving circuit comprising first and second modules, the first module being coupled to the first and second pads, and being configured to activate or deactivate the second module on the basis of the supply voltage received on the first pad and first signals received on the second pad, the second module being configured, when activated, to deliver second signals for driving the light-emitting diode for a test operation.

This patent application claims the priority of French patent application FR21/14278, which will be considered an integral part of this description.

### TECHNICAL FIELD

The present description relates generally to display pixels comprising light-emitting diodes for display screens.

### BACKGROUND ART

An image pixel corresponds to the unitary element of the image displayed by a display screen. In order to display color images, the display screen generally comprises for the display of each image pixel at least three light sources, each emitting light radiation in essentially a single color (for example, red, green, and blue). The superimposition of the radiation emitted by these three light sources provides the observer with the colored sensation corresponding to the image pixel displayed. A display pixel on a display screen can be either the set of components used to emit all the light radiation required to display a pixel of an image, or only the set of components used to emit one of the light radiation required to display a pixel of an image. The light sources of the display pixels may comprise light-emitting diodes.

Display pixels can be arranged in a matrix, with each display pixel located at the intersection of a row (or line) and a column of the matrix. In general, each row of display pixels is selected successively, and the display pixels in the selected row are programmed to display the desired image pixels.

An active matrix is a screen driver architecture that keeps all pixel lines active for the entire duration of a frame, unlike passive matrices where each line is only active for a time T=Tframe/N (where Tframe is the frame duration, and N is the number of screen lines). This makes it possible to increase the brightness of the display screen. Further, low voltage or current levels can be sent to the matrix control lines, enabling larger data streams to be displayed.

In the case of displays based on micrometric light-emitting diodes, the size of the light-emitting diodes is generally less than the surface area available on the screen for the image pixel, thanks to the high intrinsic brightness of the light-emitting diodes. One method of manufacturing a display screen involves depositing these unitary light-emitting diodes on a holder, also known as a tile, containing the driver electronics. Another manufacturing method consists in using display pixels comprising light-emitting diodes and a circuit for driving the light-emitting diodes. These are known as smart pixels. In particular, this makes it possible to simplify the production of an active matrix, since the electronics for driving the light-emitting diodes of the display pixel are essentially embedded in the display pixel. Document WO 2018/185433 describes an example of a smart pixel.

It may be desirable to perform test operations on the display pixels before or after they are attached to the tile, in particular to test the correct operation of the light-emitting diodes in the display pixels. Circuits for driving smart pixel can be digital or analog. As a result, in the case of smart pixels, performing test operations can be complex, since it requires the transmission of sequences of signals specific to the display pixels, which depend on the structure of these pixels. In particular, the performance requires the transmission, from outside the display pixel, of a complex sequence of signals to the circuit for driving the light-emitting diode, which has to be adapted to the configuration of the circuit for driving the light-emitting diode.

### SUMMARY OF INVENTION

An object of one embodiment is to provide display pixels comprising light-emitting diodes for a display screen overcoming some or all of the drawbacks of existing light-emitting diode display pixels.

An object of one embodiment is that performing display pixel test operations is easier.

An object of one embodiment is that the number of conductive pads on the display pixel is reduced.

Another object of one embodiment is that the display pixels have dimensions of less than 200 μm.

One embodiment provides a display pixel comprising at least one light-emitting diode and one electronic circuit for driving said light-emitting diode, the display pixel comprising at least one first electrically conductive pad for receiving a supply voltage for the light-emitting diode, and one second electrically conductive pad coupled to the electronic driving circuit, the electronic driving circuit being configured in normal operation to drive the light-emitting diode on the basis of first signals received on the second electrically conductive pad, the electronic driving circuit comprising first and second modules, the first module being coupled to the first and second electrically conductive pads and being configured to activate or deactivate the second module on the basis of the supply voltage received on the first electrically conductive pad and first signals received on the second electrically conductive pad, the second module being configured, when activated, to provide second signals for driving the light-emitting diode for a test operation.

Advantageously, this enables performing a test operation simply by activating the second module, which is internal to the display pixel. The test operation can be performed simply, without requiring the transmission, from outside the display pixel, of a complex sequence of signals to the circuit for driving the light-emitting diode, which would have to be adapted to the configuration of the circuit for driving the light-emitting diode.

According to one embodiment, the first module is configured to keep the second module active when, on power-up, the first electrically conductive pad receives a first voltage increasing from zero voltage to a first value, the second electrically conductive pad receives a second voltage increasing from zero voltage to a second value, and the increases in the first and second voltages are performed in a given order, and is configured to deactivate the second module when the increases in the first and second voltages are performed in an order different from the given order. Advantageously, only the order in which the first and second voltages are increased is sufficient to control whether a test operation is performed or not.

According to one embodiment, the electronic driving circuit is configured to drive the light-emitting diode by pulse-width modulation on the basis of the first signals during normal operation, and on the basis of the second signals during a test operation. This enables the light-emitting diode to be driven to its optimum operating point.

According to one embodiment, the electronic driving circuit uses an analog reference signal for pulse-width modulation control, and the second module is configured, when activated, to further deliver said analog reference signal. There is therefore no need to provide the analog reference signal to the display pixel to perform a test operation.

According to one embodiment, the electronic driving circuit uses a clock signal to clock a storage of the first signals, and the second module (43) is configured, when activated, to further deliver said clock signal. There is therefore no need to provide the clock signal to the display pixel to perform a test operation.

According to one embodiment, the first module comprises at least one logic latch providing the activation signal.

According to one embodiment, the first module comprises an inverter, the RS-type logic latch, and first and second NOR logic gates, a first input of the first logic gate being connected to the first electrically conductive pad, and a second input of the first logic gate being connected to the second electrically conductive pad, the input of the inverter being connected to the second electrically conductive pad, a first input of the second logic gate being connected to the first electrically conductive pad, and a second input of the second logic gate being connected to the output of the inverter. The structure of the first module is therefore particularly simple.

According to one embodiment, the display pixel comprises a face, the first and second electrically conductive pads being located on the face, the display pixel further comprising, on the face, at least one third electrically conductive pad electrically coupled to the driving electronic circuit, and comprising, on the face, at least one fourth electrically conductive pad, the electronic circuit comprising a controllable current source connected between an electrode of the light-emitting diode and the fourth electrically conductive pad. The number of conductive pads is thus reduced.

One embodiment also provides a display screen comprising:
display pixels as defined above;
first electrically conductive tracks coupled to the electronic circuits driving the display pixels;
a circuit for delivering first signals to the first electrically conductive tracks;
second electrically conductor tracks coupled to the electronic circuits driving the display pixels;
a circuit for delivering second signals to the second electrically conductive tracks;
third and fourth conductor tracks electrically coupled to the electronic circuits driving the display pixels; and
a circuit for delivering a supply voltage to the light-emitting diodes between the third and fourth electrically conductive tracks.

One embodiment also provides the use of a display pixel as defined above, comprising, upon power-up, providing a first voltage to the first electrically conductive pad increasing from zero voltage to a first value and a second voltage to the second electrically conductive pad increasing from zero voltage to a second value, the first module keeping the second module active when the increases in the first and second voltages are performed in a given order, and deactivating the second module when the increases in the first and second voltages are performed in an order other than the given order.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 illustrates partially and schematically an example display screen;

FIG. 2 is a very schematic cross-sectional view of an example display pixel;

FIG. 3 illustrates a block diagram of the example display pixel shown in FIG. 2 without test functionality;

FIG. 4 illustrates a block diagram of an embodiment of the display pixel shown in FIG. 2, incorporating a test functionality;

FIG. 5 illustrates a block diagram of an embodiment of part of the control circuit of the display pixel shown in FIG. 4;

FIG. 6 illustrates a block diagram of an embodiment of another part of the control circuit of the display pixel shown in FIG. 4;

FIG. 7 illustrates a block diagram of an embodiment of another part of the control circuit of the display pixel shown in FIG. 4;

FIG. 8 is a bottom view of an embodiment of the display pixel shown in FIG. 4;

FIG. 9 illustrates a block diagram of a circuit for detecting a test operation of the display pixel shown in FIG. 4;

FIG. 10 illustrates chronograms of signals provided to the display pixel shown in FIG. 4 with the detection circuit shown in FIG. 9 in normal operation;

FIG. 11 illustrates chronograms of signals provided to the display pixel shown in FIG. 4 having the detection circuit of FIG. 12 to perform a test operation; and

FIG. 12 illustrates, partially and schematically, an assembly for performing a test operation.

### DESCRIPTION OF EMBODIMENTS

Like features have been designated by like references in the various figures. In particular, the structural and/or functional features that are common among the various embodiments may have the same references and may dispose identical structural, dimensional and material properties. For the sake of clarity, only the operations and elements that are useful for an understanding of the embodiments described herein have been illustrated and described in detail.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures, or to a display screen as orientated during normal use.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

Furthermore, unless otherwise specified, when we speak of a voltage at a conductive pad, we consider the difference between the potential at said conductive pad and a reference potential, e.g. ground, taken to be equal to 0 V. In addition, a “binary signal” is a signal that alternates between a first constant state, for example a low state, denoted “0”, and a second constant state, for example a high state, denoted “1”. The high and low states of different binary signals from the same electronic circuit can be different. In practice, binary signals may correspond to voltages or currents which may not be perfectly constant at the high or low state.

Further, we consider here the terms “insulator” and “conductor” as taken to mean “electrically insulating” and “electrically conductive” respectively. Unless specified otherwise, the expressions “around”, “approximately”, “substantially” and “in the order of” signify within 10%, and preferably within 5%.

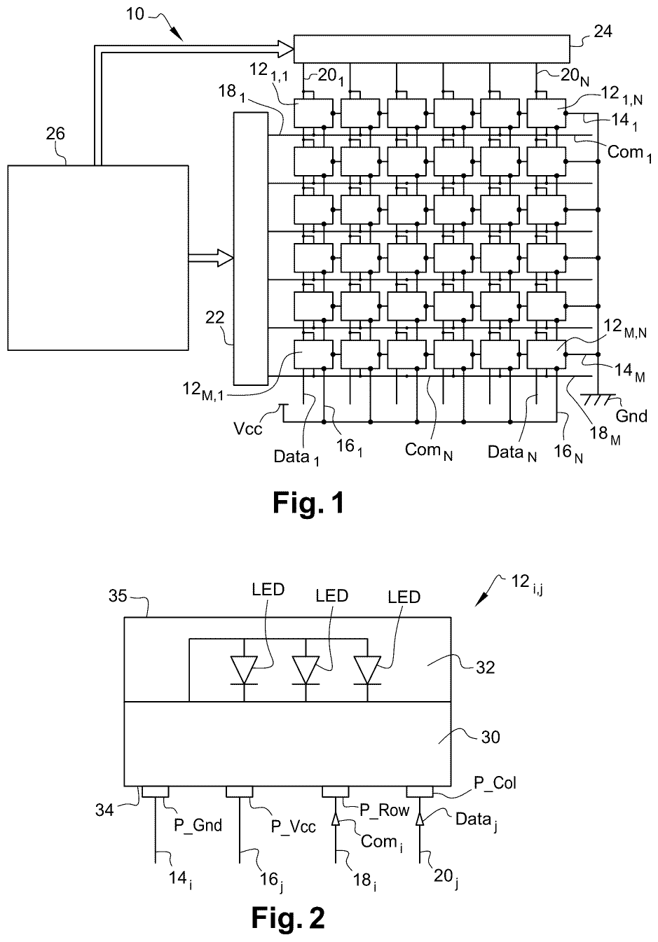

FIG. 1 illustrates partially and schematically of a known example of a display screen 10. The display screen 10 comprises display pixels 12_{i,j} for example arranged in M rows and N columns, M being an integer varying from 1 to 8000, and N being an integer varying from 1 to 16000, i being an integer varying from 1 to M, and j being an integer varying from 1 to N. By way of example, in FIG. 1, M and N are equal to 6. Each display pixel 12_{i,j} is coupled to a source of a low reference potential Gnd, e.g. ground, via an electrode 14; and to a source of a high reference potential Vcc via an electrode 16ⱼ. By way of example, the electrodes 14; are shown aligned along the rows in FIG. 1, and the electrodes 16ⱼ are shown aligned along the columns in FIG. 1, the reverse arrangement being possible. The supply voltage of the display corresponds to the voltage between the high reference potential Vcc and the low reference potential Gnd, and is denoted Vcc as the high reference potential. The supply voltage Vcc depends in particular on the arrangement of the light-emitting diodes and the technology used to manufacture light-emitting diodes. By way of example, the supply voltage Vcc can be in the range of 4 V to 5 V.

For each row, the display pixels 12_{i,j} of the row are coupled to a row electrode 18ᵢ. For each column, the display pixels 12_{i,j} of the column are coupled to a column electrode 20ⱼ. The display screen 10 comprises a selection circuit 22 coupled to the row electrodes 18ᵢ, and adapted to provide a selection signal Comᵢ on each row electrode 18ᵢ. The display screen 10 comprises a data supply circuit 24 coupled to the column electrodes 20ⱼ and adapted to provide a data signal Dataⱼ on each column electrode 20ⱼ. The selection circuit 22 and the control circuit 24 are controlled by a circuit 26, comprising for example a microprocessor.

FIG. 2 is a very schematic cross-sectional view of an example display pixel 12_{i,j}. Each display pixel 12_{i,j} comprises a control circuit 30 covered by a display circuit 32. Display circuit 32 comprises at least one light-emitting diode LED, three light-emitting diodes LED being shown as an example in FIG. 2. The display pixel comprises a lower face 34 and an upper face 35 opposite the lower face 34, faces 34 and 35 preferably being flat and parallel. The control circuit 30 further comprises conductive pads P_Gnd, P_Vcc, P_Col, P_Row on the lower face 34. The control circuit 30 may correspond to an integrated circuit comprising electronic components, in particular insulated-gate field-effect transistors, also known as MOS transistors, or thin-film transistors, also known as TFT transistors. Preferably, the display circuit 32 comprises only the light-emitting diodes LED, and the conductive elements of these light-emitting diodes LED, and the control circuit 30 comprises all the electronic components required to control the light-emitting diodes LED of the display circuit 32. Alternatively, the display circuit 32 can also comprise other electronic components in addition to the light-emitting diodes LED. The light-emitting diodes LED can be 2D light-emitting diode, also known as planar light-emitting diode, comprising a stack of planar layers, or 3D light-emitting diodes, each comprising a three-dimensional semiconductor element covered by an active zone. In FIG. 2, the light-emitting diodes LED are shown connected as a common anode. However, it may be desirable to arrange the light-emitting diodes LED in a different configuration. By way of example, the light-emitting diodes LED may be connected as a common cathode, or they may be connected independently of each other.

As will be described in more detail later, the control circuit 30 of the display pixel 12_{i,j} incorporates functionalities for testing the correct operation of the display pixel 12_{i,j}.

According to one embodiment, the display pixel 12_{i,j} comprises three light sources emitting light at first, second, and third wavelengths. According to one embodiment, the first wavelength corresponds to blue light, and is in the range from 430 nm to 490 nm. According to one embodiment, the second wavelength corresponds to green light, and is in the range from 510 nm to 570 nm. According to one embodiment, the third wavelength corresponds to red light, and is in the range from 600 nm to 720 nm. Alternatively, the display pixel 12_{i,j} may comprise only one light source emitting light at the first, second, or third wavelength, or only two light sources emitting light at two wavelengths among the first, second, and third wavelengths.

Each conductive pad P_Gnd, P_Vcc, P_Col, P_Row is intended to be connected to one of the electrodes 14ᵢ, 16ⱼ, 18ᵢ, 20ⱼ shown schematically in FIG. 2. The first conductive pad P_Gnd is coupled to the source of the low reference potential Gnd. The second conductor pad P_Vcc is coupled to the source of the high reference potential Vcc. The third conductor pad P_Row is coupled to the row electrode 18ᵢ, and receives the selection signal Comᵢ. The fourth conductive pad P_Col is coupled to the column electrode 20ⱼ, and receives the data signal Dataⱼ. The dimensions of the conductive pads P_Gnd, P_Vcc, P_Col, P_Row and the arrangement of the conductive pads P_Gnd, P_Vcc, P_Col, P_Row on the face 34 are imposed in particular by the design rules of the display pixel 12_{i,j} and by the method of assembling the display pixels 12_{i,j} in the display screen 10.

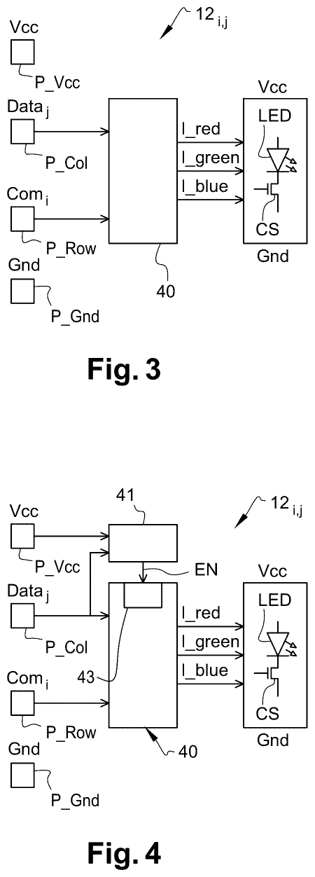

FIG. 3 illustrates an example of a block diagram of a display pixel 12_{i,j} of the display screen 10 not incorporating a test functionality.

According to one example, the display pixel 12_{i,j} comprises a light-emitting diode or light-emitting diodes, a single light-emitting diode LED being shown as an example in FIG. 3. Each light-emitting diode LED is coupled in series to a controllable current source CS, comprising for example a MOS transistor. In the present example, for each light-emitting diode LED, the anode of the light-emitting diode LED is coupled, for example, to the conductive pad P_Vcc receiving the high reference potential Vcc, and the cathode of the light-emitting diode LED is coupled, for example, to one terminal of the controllable current source CS, the other terminal of the controllable current source CS being coupled to the conductive pad P_Gnd receiving the low reference potential Gnd. Alternatively, the cathode of the light-emitting diode LED is coupled, for example, to the conductive pad P_Gnd at the low reference potential Gnd, and the anode of the light-emitting diode LED is coupled, for example, to one terminal of the controllable current source CS, the other terminal of the controllable current source CS being coupled to the conductive pad P_Vcc receiving the high reference potential Vcc.

The display pixel 12_{i,j} further comprises a circuit 40 for driving the controllable current source CS. In particular, the driving circuit 40 may comprise electronic components such as MOS transistors. The driving circuit 40 may be formed, in whole or in part, in the control circuit 30.

FIG. 4 illustrates a block diagram embodiment of a display pixel 12_{i,j} of the display screen 10 incorporating test functionality. The display pixel 12_{i,j} shown in FIG. 4 comprises all the elements of the display pixel 12_{i,j} shown in FIG. 3, the driving circuit 40 further comprising a circuit 41 for detecting a test operation. The circuit 41 for detecting a test operation receives the signals received on at least two conductive pads, and provides an activation signal EN to a test module of the driving circuit 40. In the present embodiment, the circuit 41 for detecting a test operation receives the supply voltage Vcc received at the conductive pad P_Vcc and the data signal Dataⱼ received at the conductive pad P_Col. According to one embodiment, the activation signal EN is a binary signal. When the activation signal EN is in logic state “1”, the test module 43 is activated, so that the driving circuit 40 performs a test operation, and when the activation signal EN is in logic state “0”, the test module 43 is inactivated, so that the driving circuit 40 operates normally.

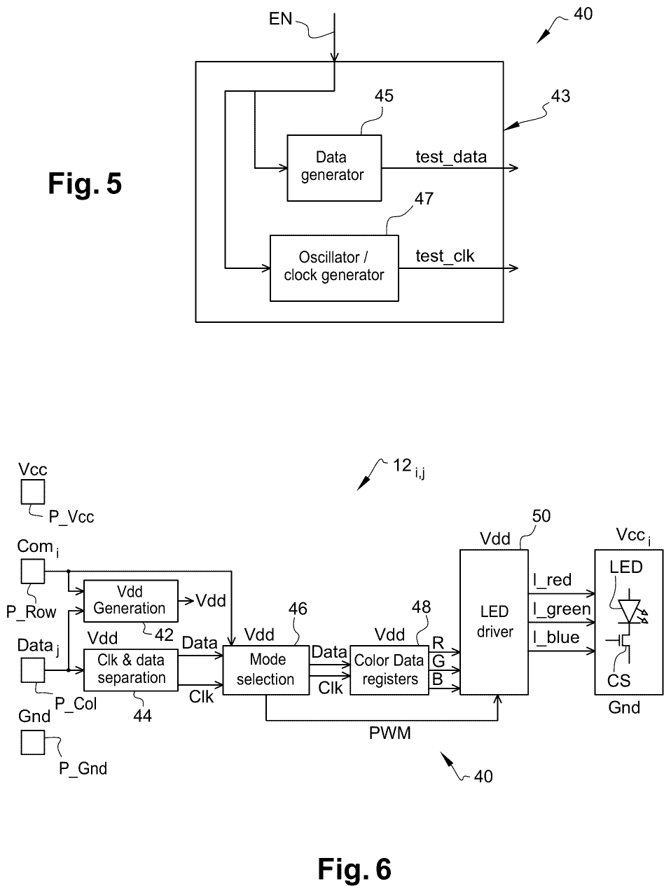

FIG. 5 illustrates a block diagram of an embodiment of the test module 43 of the driving circuit 40 of the display pixel 12_{i,j} shown in FIG. 4. The test module 43 comprises a data generator 45 (Data generator), which receives the activation signal EN and outputs a test data signal test_data. The test module 43 further comprises a clock module 45 (Oscillator/Clock generator), which receives the activation signal EN and outputs a clock signal test_clk. The signals test_data and test_clk can be binary, digital, or analog signals, depending on the structure of the driving circuit 40. When the test module 43 is activated for a test operation, the light-emitting diode is driven on the basis of the signals test_data and test_clk delivered by the test module 43.

FIG. 6 illustrates an example block diagram of a display pixel 12_{i,j} of the display screen 10 illustrating an embodiment of part of the driving circuit 40 in the case where the selection signal Comᵢ, received at the conductive pad P_Row of each display pixel 12_{i,j}, is a binary signal alternating between a low logic state “0” and a high logic state “1”, and the data signal Dataⱼ is a binary signal alternating between a low logic state “0” and a high logic state “1”. For the signals Comᵢ and Dataⱼ, the low logic state corresponds to the low reference potential Gnd, and the high logic state “1” corresponds to a low voltage, substantially equal to a reduced supply voltage Vdd.

In FIG. 6, above each block, the supply voltage used to power the electronic components of the block is indicated. The display pixel 12_{i,j} may comprise a supply circuit 42 (Vdd Generation), receiving the selection signal Comᵢ and the data signal Dataⱼ, and adapted to deliver the reduced supply voltage Vdd on the basis of the selection signal Comᵢ and the data signal Dataⱼ, the reduced supply voltage Vdd being for example less than 4 V, in particular of the order of 1 V or 1.8 V, used in particular for providing the driving circuit 40. According to one embodiment, the circuit 42 may comprise a capacitor charged by the selection signal Comᵢ and the data signal Dataⱼ. Alternatively, the display pixel 12_{i,j} may comprise an additional conductive pad receiving the reduced voltage Vdd.

The driving circuit 40 comprises a circuit 44 (Clk & data separation) coupled to the conductive pad P_Col receiving the data signal Dataⱼ and providing, on the basis of the data signal Dataⱼ, a clock signal Clk and data Data. The driving circuit 40 comprises a circuit 46 (Mode selection) receiving the signals Clk and Data, coupled to the conductive pad P_Row receiving the selection signal Comᵢ, and configured to provide the signals Clk and Data to a storage circuit 48 (Color Data registers), or to provide a signal PWM to a circuit 50 (LED driver) driving the controllable current source CS associated with each light-emitting diode LED. Memory circuit 48 is configured to store digital color signals R, G, B representative of the image pixel to be displayed. Circuit 50 is adapted to control the controllable current sources CS coupled to the light-emitting diodes LED with signals I_red, I_green, and I_blue, obtained from the color signals R, G, B, and the signal PWM. Alternatively, in the case of a monochromatic display pixel, the memory circuit 48 is configured to store a single analog color signal, and the circuit 50 is adapted to drive the controllable current sources CS coupled to the light-emitting diodes LED with commands obtained from the analog color signal and the analog reference signal.

According to one embodiment, in order to limit the number of conductive pads P_Gnd, P_Vcc, P_Col, P_Row per display pixel 12_{i,j}, the data signals Dataⱼ enable both the determination, by each display pixel 12_{i,j}, of a clock signal and the color signals R, G, B representing the desired light intensities for radiation at the first, second, and third wavelengths, or, in the case of a monochromatic display pixel, the color signal representing the desired light intensity for radiation at the single wavelength. According to another example, the clock signal Clk is obtained from the selection signal Comᵢ.

Each light-emitting diode LED can be controlled by pulse width modulation, also known as PWM (Pulse Width Modulation) control. This type of control consists in flowing successive current pulses of constant intensity through the light-emitting diode LED, the pulses being repeated cyclically, the duty cycle determining the light intensity emitted by the light-emitting diodes. Advantageously, such a control enables the light-emitting diode to be operated at its optimum operating point, where the efficiency of the light-emitting diode, equal to the ratio between the light power emitted by the light-emitting diodes and the electrical power consumed by the light-emitting diode, is at its maximum. In this case, the signal PWM may correspond to a sequence of pulses used to perform PWM control of the light-emitting diode LED.

In the embodiment of the driving circuit 40 shown in FIG. 6, when the test module 43 is activated, corresponding for example to an activation signal EN at logic state “1”, the clock signal test_clk delivered by module 47 of the test module 43 shown in FIG. 5 may correspond to a clock signal analogous to the signal Clk, and the data signal test_data delivered by module 45 of the test module 43 shown in FIG. 5 may correspond to a binary signal analogous to the signal Data. The light-emitting diodes LED are driven on the basis of the signals test_data provided at the rate of the clock signal test_clk. When the test module 43 is activated, corresponding for example to an activation signal EN in logic state “1”, the signals test_clk and test_data are at 0 V.

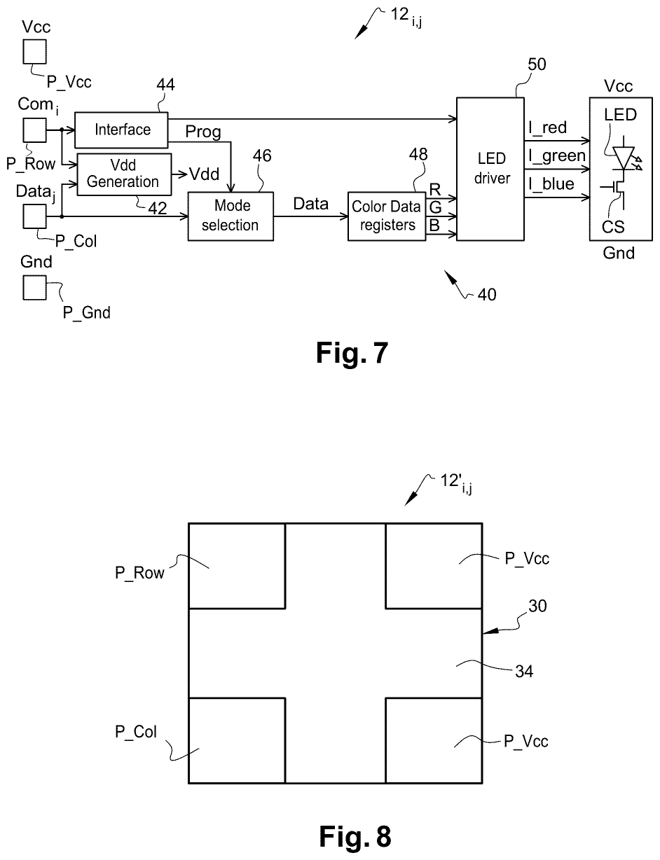

FIG. 7 illustrates an example of a block diagram of a display pixel 12_{i,j} of the display screen 10 illustrating another embodiment of part of the driving circuit 40 in the case where the selection Comᵢ and reference PWM signal, received at the conductive pad P_Row of each display pixel 12_{i,j}, is an analog signal, and the data signal Dataⱼ, received at the conductive pad P_Col of each display pixel 12_{i,j}, is an analog signal.

The display pixel 12_{i,j} shown in FIG. 7 has the same structure as the display pixel 12_{i,j} shown in FIG. 6, with the difference that the signal PWM is an analog reference signal, generally periodic, varying continuously between a minimum value and a maximum value, for example a succession of voltage ramps. In addition, the circuit 44 (Interface) is coupled to the conductive pad P_Row receiving the selection Comᵢ and reference PWM signal and provides, on the basis of the signal Comᵢ, a selection signal Prog and the analog reference signal PWM. Circuit 46 (Mode selection) receives the data signal Dataⱼ and the selection signal Prog, and is configured to provide an analog signal Data to memory circuit 48 (Color Data Memory). The memory circuit 48 is configured to store analog color signals R, G, B representative of the image pixel to be displayed, using capacitors for example, and the circuit 50 is adapted to control the controllable current sources CS coupled to the light-emitting diodes LED with commands obtained from the analog color signals R, G, B, and the analog reference signal PWM. By way of example, circuit 50 compares the analog color signal R, G, B with the analog reference signal PWM and switches the controllable current source CS on or off depending on the result of the comparison.

In the embodiment of the driving circuit 40 shown in FIG. 7, when the test module 43 is activated, corresponding for example to an activation signal EN at logic state “1”, the signal test_clk provided by the test module 43 shown in FIG. 5 may correspond to the signal PWM, and the signal test_data delivered by the module 45 of the test module 43 shown in FIG. 5 may correspond to an analog signal analogous to the signal Data. The light-emitting diodes LED are controlled on the basis of the signals test_data according to a PWM control using the signal test_clk. When the test module 43 is activated, corresponding for example to an activation signal EN in logic state “1”, the signals test_clk and test_data are at 0 V.

FIG. 8 is a bottom view of the display pixel 12_{i,j}. The lower face 34 of the display pixel 12_{i,j} is square-shaped, and each pad P_Gnd, P_Vcc, P_Col, P_Row is, in a direction perpendicular to the face 34, square-shaped, the pads P_Gnd, P_Vcc, P_Col, P_Row being located at the four corners of the face 34.

It is generally desirable for display pixel dimensions to be as small as possible, in order to reduce the amount of semiconductor materials used in the display pixels, and therefore to reduce the cost of manufacturing these display pixels. For a smart pixel, it is generally the number of smart pixel conductive pads, used for the electrical connection of the smart pixel to the tile, that dictates the dimensions of the smart pixel, particularly because of the minimum size of these pads and the minimum space that must be provided between these pads. The display pixel 12_{i,j} shown in FIG. 8 advantageously has a reduced number of conductive pads P_Gnd, P_Vcc, P_Col, P_Row.

The display pixel 12_{i,j} may have a generally cylindrical shape with a cross-section which, when viewed from above, may have different shapes, such as, for example, an oval, circular, or polygonal shape, particularly triangular, rectangular, square, or hexagonal. The maximum lateral dimension of the display pixel 12_{i,j} in plan view can be between 10 μm and 500 μm. The thickness of the display pixel 12_{i,j} can be between 20 μm and 750 μm. The thickness of control circuit 30 can be between 10 μm and 725 μm. The thickness of display circuit 32 can be between 10 μm and 725 μm.

Each conductor pad P_Gnd, P_Vcc, P_Col, P_Row can have a generally cylindrical shape with a straight cross-section that can have different shapes, such as, for example, oval, circular, or polygonal, in particular triangular, rectangular, square, or hexagonal. When viewed from below, each pad P_Gnd, P_Vcc, P_Col, P_Row can be inscribed in a square whose side can vary between 1 μm and 200 μm. The conductive pads P_Gnd, P_Vcc, P_Col, P_Row are made of metal, for example aluminum, silver, platinum, nickel, copper, gold, or ruthenium, or of an alloy comprising at least two of these compounds, in particular the PdAgNiAu alloy or the PtAgNiAu alloy.

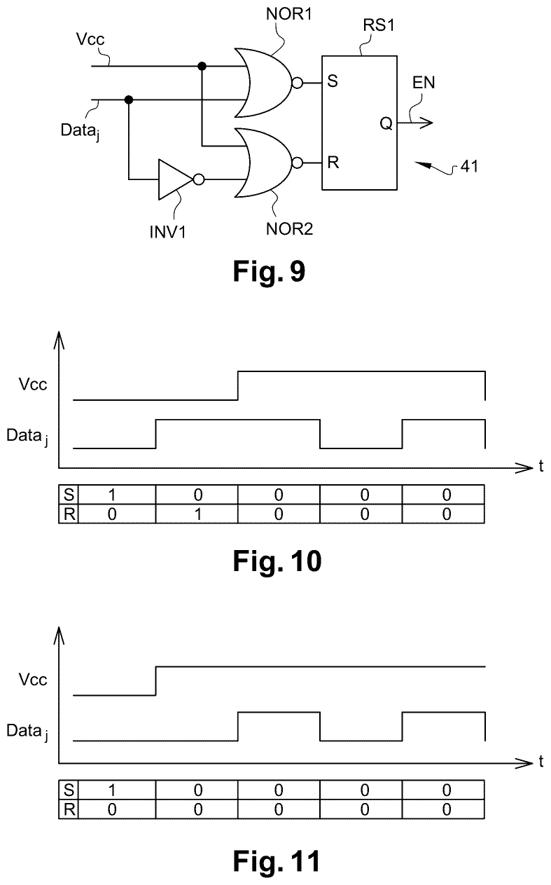

FIG. 9 is a block diagram of an embodiment of the circuit 41 for detecting a test operation. In the present embodiment, the circuit 41 comprises a first logic gate NOR1 of the NOR type, a first input of which receives the voltage Vcc and a second input of which receives the signal Dataᵢ. The circuit 41 comprises an inverter INV1 receiving the signal Dataᵢ as input. The circuit 41 comprises a second logic gate NOR2 of the NOR type, a first input of which receives the voltage Vcc, and a second input of which receives the output of the inverter INV1. Circuit 41 further comprises a logic latch RS1 of RS type. The input S of the latch RS1 is coupled to the output of logic gate NOR1, the input R of the latch RS1 is connected to the output of the logic gate NOR2, and the output Q of the latch RS1 provides the activation signal EN. For an RS-type latch, when the logic state of input S is set to “1”, output Q goes to logic state “1”, when the logic state of input R is set to “1”, output Q goes to logic state “0”, and when inputs R and S are in logic state “0”, output Q maintains its previous value.

FIG. 10 illustrates chronograms of the signals Vcc and Dataⱼ provided to the detection circuit 41 shown in FIG. 9 to obtain normal operation of the display pixel 12_{i,j} and the obtained logic states of the inputs S and R of the latch RS1.

When the display pixel 12_{i,j} is powered up for normal use, i.e. without performing a test operation, the data signal Dataⱼ is brought to its maximum value before the supply voltage Vcc is brought to its maximum value. Initially, the voltage Vcc and the data signal Dataⱼ are at 0 V, the input S of the latch RS1 is at logic “1”, and the input R of the latch RS1 is at logic “0” so that the activation signal EN is at logic “1”. When the data signal Dataⱼ is brought to its maximum value while the supply voltage Vcc is still at 0 V, the input S of the latch RS1 goes to the logic state “0” and the input R of the latch RS1 goes to the logic state “1”, so that the activation signal EN goes to the logic state “0”. The test module 43 is then inactive. As long as the voltage Vcc is at its maximum value, the activation signal EN remains in logic state “0”, whatever the subsequent state of the signal Dataⱼ. When the reduced voltage Vdd is generated inside the display pixel 12_{i,j}, the selection signal Comᵢ can be set to “1” before the data signal Dataⱼ and the supply voltage Vcc, so that the detection circuit 41 is powered.

FIG. 11 illustrates chronograms of the signals Vcc and Dataj provided to the detection circuit 41 shown in FIG. 9 to perform a test operation on the display pixel 12_{i,j} and the obtained logic states of the inputs S and R of the latch RS1.

When the display pixel 12_{i,j} is powered up to perform a test operation, the data signal Dataⱼ is brought to its maximum value after the supply voltage Vcc is brought to its maximum value. Initially, the voltage Vcc and the data signal Dataⱼ are at 0 V, the input S of the latch RS1 is at logic state “1”, and the input R of the latch RS1 is at logic state “0” so that the activation signal EN is at logic state “1”. When the supply voltage Vcc is brought to its maximum value while the data signal Dataⱼ is still at 0 V, the input S of the latch RS1 goes to logic state “0” and the R input of the latch RS1 remains at logic state “0”, so that the activation signal EN remains at state “1”. Test module 43 then remains activated. As long as the voltage Vcc is at its maximum value, the activation signal EN remains in logic state “1”, whatever the subsequent state of the signal Dataⱼ.

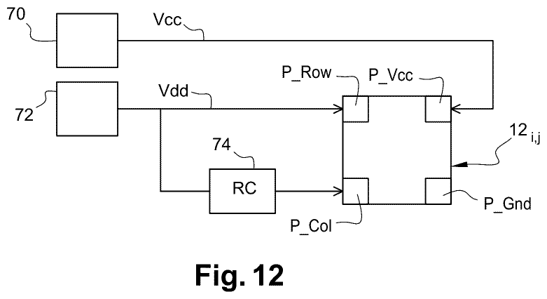

FIG. 12 schematically illustrates the implementation of a test operation for a display pixel 12_{i,j}. A generator 70 of the voltage Vcc is connected to the pad P_Vcc of the display pixel 12_{i,j}. A generator 72 for the voltage Vdd is connected directly to the pad P_Row, and is connected to the pad P_Col via an RC-type filter 74 (RC), which allows a delay in the rise in voltage at the pad P_Col to be obtained relative to the rise in voltage at the pad P_Vcc. An advantage of the present embodiment is that a test operation can be performed by a test tool of simple design.

One embodiment of a method of manufacturing a display screen comprises the following steps:
forming an optoelectronic plate, and forming a logic plate. The optoelectronic plate comprises the light-emitting diodes of the display circuits of several display pixels. The logic plate comprises the logic circuits for controling several display pixels;
attaching the optoelectronic plate to the logic plate;
cutting the stack of optoelectronic plate and logic plate to separate the display pixels. This step can be performed by sawing; and
transferring display pixels onto a display screen tile.

The display pixel test operations described above can be performed after or before the cutting step, or after transferring the display pixels to the display screen tile, preferably before the cutting step. By way of example, during an operation to test a display pixel 12_{i,j}, can be used a device for receiving the light radiation emitted from the display pixel (possibly independently of all the other display pixels on a plate), and for processing the emitted light radiation to determine the state of the display pixel. This may enable display pixels to be sorted between functional and non-functional display pixels.

Particular embodiments have been described. Various variants and modifications will become apparent to those skilled in the art. In particular, in the embodiments described above, the rise in voltage at the pad P_Vcc before the rise in voltage at the pad P_Col triggers a test operation of the display pixel 12_{i,j}, and the rise in voltage at the pad P_Col before the rise in voltage at the pad P_Vcc triggers normal operation of the display pixel 12_{i,j}. Alternatively, however, it may be provided that it is the rise in voltage at pad P_Vcc before the rise in voltage at pad P_Col that triggers normal operation of display pixel 12_{i,j} and the rise in voltage at pad P_Col before the rise in voltage at pad P_Vcc that triggers performance of a test operation of display pixel 12_{i,j}. In addition, various embodiments with different variants have been described above. It should be noted that various elements of these various embodiments and variants can be combined.

1. A display pixel comprising at least one light-emitting diode and an electronic circuit for driving said light-emitting diode, the display pixel comprising at least one first electrically conductive pad for receiving a supply voltage for the light-emitting diode, and one second electrically conductive pad coupled to the electronic driving circuit, the electronic driving circuit being configured in normal operation to drive the light-emitting diode on the basis of first signals received on the second electrically conductive pad, the electronic control circuit comprising first and second modules, the first module being coupled to the first and second electrically conductive pads, and being configured to activate or deactivate the second module on the basis of the supply voltage received on the first electrically conductive pad and first signals received on the second electrically conductive pad, the second module being configured, when activated, to provide second signals for driving the light-emitting diode for a test operation.

2. The display pixel according to claim 1, wherein the first module is configured to keep the second module active when, on power-up, the first electrically conductive pad receives a first voltage increasing from zero voltage to a first value, the second electrically conductive pad receives a second voltage increasing from zero voltage to a second value, and the increases in the first and second voltages are performed in a given order and is configured to deactivate the second module when the increases in the first and second voltages are performed in an order different from the given order.

3. The display pixel according to claim 1, wherein the electronic driving circuit is configured to drive the light-emitting diode by pulse-width modulation on the basis of the first signals during normal operation, and on the basis of the second signals during a test operation.

4. The display pixel according to claim 3, wherein the electronic driving circuit uses an analog reference signal for pulse width modulation control, and wherein the second module is configured, when activated, to additionally provide said analog reference signal.

5. The display pixel according to claim 1, wherein the electronic driving circuit uses a clock signal to clock a storage of the first signals, and wherein the second module is configured, when activated, to further provide said clock signal.

6. The display pixel according to claim 1, wherein the first module comprises at least one logic latch providing the activation signal.

7. The display pixel according to claim 6, wherein the first module comprises an inverter, the logic latch of type RS, and first and second logic gates of NOR-type, a first input of the first logic gate being connected to the first electrically conductive pad, and a second input of the first logic gate being connected to the second electrically conductive pad, the input of the inverter being connected to the second electrically conductive pad, a first input of the second logic gate being connected to the first electrically conductive pad, and a second input of the second logic gate being connected to the output of the inverter.

8. The display pixel according to claim 1, comprising a face (34), the first and second electrically conductive pads being located on the face, the display pixel further comprising, on the face (34), at least one third electrically conductive pad electrically coupled to the electronic driving circuit, and comprising, on the face, at least one fourth electrically conductive pad, the electronic circuit comprising a controllable current source connected between an electrode of the light-emitting diode and the fourth electrically conductive pad.

9. A display screen comprising:
display pixels according to any one of claim 1;
first electrically conductive tracks coupled to the electronic circuit driving the display pixels;
a circuit for delivering third signals to the first electrically conductive tracks;
second electrically conductive tracks coupled to the electronic circuit driving the display pixels;
a circuit for delivering the first signals to the second electrically conductive tracks;
third and fourth electrically conductive tracks coupled to the electronic control circuits of the display pixels; and
a circuit for delivering a supply voltage to the light-emitting diodes between the third and fourth electrically conductive tracks.

10. A use of a display pixel according to claim 1, comprising, upon power-up, providing a first voltage to the first electrically conductive pad increasing from zero voltage to a first value and a second voltage to the second electrically conductive pad increasing from zero voltage to a second value, wherein the first module keeps the second module active when the increases in the first and second voltages are performed in a given order, and deactivates the second module when the increases in the first and second voltages are performed in an order different from the given order.
